(19) United States
(12) Patent Application Publication
(10) Pub. No.: US 2018/0040797 A1
(43) Pub. Date: Feb. 8, 2018

(54) THERMOELECTRIC TRANSDUCER

(71) Applicant: Sharp Kabushiki Kaisha, Osaka (JP)

(72) Inventors: Tomoya TSUTSUMINO, Sakai City (JP); Yoshitaka KAWASE, Sakai City (JP)

(21) Appl. No.: 15/662,324

(22) Filed: Jul. 28, 2017

(30) Foreign Application Priority Data
Aug. 5, 2016 (JP) 2016-154598

(51) Int. Cl. H01L 35/32; H01L 35/24

(52) U.S. Cl. CPC H01L 35/32; H01L 35/24

(57) ABSTRACT

A thermoelectric transducer includes a stretchable and bendable core having a surface covered with an organic compound selected from conductive polymers and organic charge transfer complexes that have thermoelectric properties.

### CROSS-REFERENCE TO RELATED APPLICATION

This application is related to Japanese Patent Application No. 2016-154598 filed on Aug. 5, 2016, whose priority is claimed under 35 USC § 119, and the disclosures of which are incorporated by reference in their entirety.

### BACKGROUND

### 1. Field

The present disclosure generally relates to thermoelectric transducers and particularly to a flexible and stretchable thermoelectric transducer.

### 2. Description of the Related Art

Currently, Japan is heavily dependent on imports of primary energy such as oil and coal. It is said that about 60% of all energy generated by using the primary energy is wasted as unused thermal energy.

Thermoelectric generation is attracting attention as a way to utilize this unused thermal energy. It is believed that the unused thermal energy can be recovered as highly useful electric energy through thermoelectric transducers. Due to this reason, much efforts have been put into development of thermoelectric transducers. Thermoelectric transducers alone or as modules combining many thermoelectric transducers are already used not only for power generation on the ground but also as power supplies for space satellites. Investigations are now being conducted to find use of not only such large heating elements but also small heating elements for automobiles, motorcycles, etc.

Thermoelectric transducers that have been commonly used so far include a junction of two dissimilar metals or semiconductors or a combination of a p-type semiconductor and an n-type semiconductor. However, such thermoelectric transducers have little flexibility.

In recent years, conductive polymers have attracted attention as materials for forming flexible thermoelectric transducers. However, even the thermoelectric transducers that use flexible conductive polymers may not be suitable for bending depending on the thermoelectric material used. Such a thermoelectric transducer may crack and fail to conduct when bent.

Reducing the thickness of a thermoelectric transducer that uses a conductive polymer improves flexibility; however, reducing the thickness also reduces the cross-sectional area of the conductive polymer in the current direction and may degrade electrical conductivity.

In view of practical application of thermoelectric transducers, thermoelectric transducers that use conductive polymers have lower electrical conductivity than inorganic thermoelectric transducers that are already available. Reducing the thickness to improve flexibility would further lower electrical conductivity, and thus may not be desirable from the viewpoint of energy conversion efficiency.

Recently, there have been disclosed a thermoelectric element prepared by using a porous matrix or a porous substrate, and making of an inexpensive, highly flexible, and highly versatile thermoelectric elements; however, specific flexibility of the thermoelectric element is not mentioned (for example, see Japanese Unexamined Patent Application Publication (Translation of PCT Application) No. 2010-510682).

There have also been disclosed a first thermoelectric material formed of a composite that includes a support, an organic compound supported on a surface of the support and having electric conductivity and thermoelectric properties, and a dopant supported at the interface of the support and the organic compound; and a second thermoelectric material formed of a composite that includes a porous support, and an organic compound supported in pores of the support and having electrical conductivity and thermoelectric properties. The flexibility of these thermoelectric materials is not mentioned (for example, see Japanese Unexamined Patent Application Publication No. 2006-128444).

### SUMMARY

It is desirable to provide an inexpensive thermoelectric transducer that is flexible and stretchable.

On the basis of studies, it has been found that covering a surface of a stretchable core with a conductive polymer helps address the issues described above.

The present disclosure provides a thermoelectric transducer that includes a core that is stretchable and bendable; and a coating film on a surface of the core, the coating film being formed of an organic compound selected from conductive polymers and organic charge transfer complexes that have thermoelectric properties.

### BRIEF DESCRIPTION OF THE DRAWINGS

FIG. 1 is a sample illustration of a portion of a thermoelectric transducer;

FIG. 2 includes a partial enlarged conceptual diagram of a portion of the thermoelectric transducer and an enlarged cross-sectional view of a twisted thread that constitutes the transducer; and

FIG. 3 is a schematic diagram illustrating the thermoelectric transducer and a method for determining electromotive force of the thermoelectric transducer.

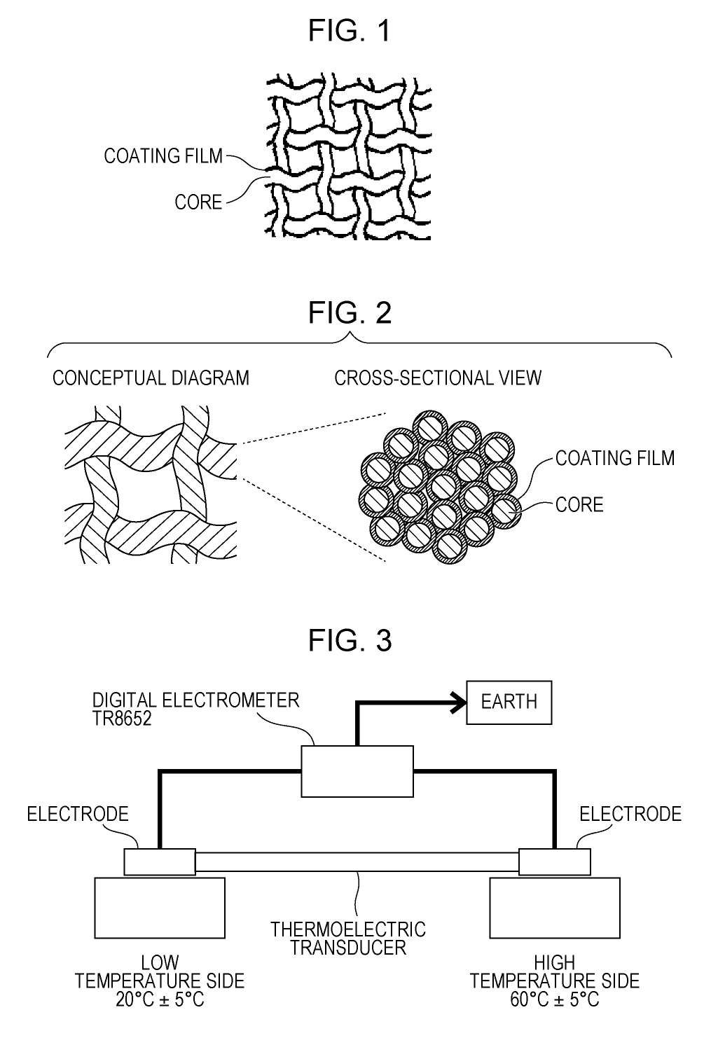

### DESCRIPTION OF THE EMBODIMENTS

Examples of the fibers that constitute a stretchable core according to the present disclosure include cotton, silk, hemp, mohair, wool, cashmere, acetate fibers, cupra fibers, rayon fibers, lyocell fibers, polynosic fibers, recycled polyester fibers, elastomer fibers, spandex fibers, nylon fibers, aramid fibers, vinylon fibers, polyvinylidene chloride fibers, polyvinyl chloride fibers, polyester fibers, polyacrylonitrile fibers, polyethylene fibers, polypropylene fibers, polyurethane fibers, polychlal fibers, polylactide fibers, alginate fibers, polytributylene terephthalate fibers, polybutylene terephthalate fibers, rubber fibers, and carbon fibers.

Fibers can be categorized into non-stretchable fibers and stretchable fibers as follows.

### Non-Stretchable Fibers

Examples of the non-stretchable fibers include cotton, silk, hemp, mohair, wool, cashmere, acetate fibers, cupra fibers, rayon fibers, lyocell fibers, polynosic fibers, recycled polyester fibers, nylon fibers, aramid fibers, vinylon fibers, polyvinylidene chloride fibers, polyvinyl chloride fibers, polyester fibers, polyacrylonitrile fibers, polyethylene fibers, polypropylene fibers, polychlal fibers, polylactide fibers, alginate fibers, and carbon fibers.

### Stretchable Fibers

Examples of the stretchable fibers include polyurethane fibers, elastomer fibers, spandex fibers, polytributylene terephthalate fibers, polybutylene terephthalate fibers, and rubber fibers.

Single fibers of the non-stretchable and stretchable fibers described above can be woven depending on the thickness of the fibers. Two or more of such fibers may be twisted and used as a twisted thread to ensure strength.

Non-stretchable fibers (hereinafter this term also covers non-stretchable twisted threads) and stretchable fibers (hereinafter this term also covers stretchable twisted threads) may be woven into a stretchable core used in the present disclosure.

The raw material used in constructing the thermoelectric transducer according to the present disclosure is a fiber material given stretchability by weaving a stretchable material into a nonwoven cloth or a woven cloth. This fiber material is used as a core, and a conductive polymer is attached to the core to prepare a flexible and bendable thermoelectric transducer.

Although the conductive polymer itself is a flexible material, cracks may occur upon bending due to the properties of the raw material onto which the conductive polymer is applied or due to the thickness of the coating film. In the present disclosure, the conductive polymer is attached to the core so that cracking can be reduced and electric conduction can be maintained even when the transducer is bent or elongated.

### Organic Compound Having Thermoelectric Properties

An organic compound having thermoelectric properties has electrical conductivity and thermoelectric properties, and covers the surface of the core, a twisted thread that constitutes the core, or fibers that constitute the twisted thread.

Examples of the organic compound having the thermoelectric properties include conductive polymers and organic charge transfer complexes. With these organic compounds, electrical resistance and the like can be adjusted by changing the dopant type or concentration.

### Conductive Polymer

Specifically, a polymer compound having a conjugated molecular structure can be used.

A polymer (conjugated polymer) having a conjugated molecular structure is a polymer having a structure in which single bonds and double bonds alternate in the carbon-carbon bonds of the polymer main chain, or a polymer having a structure in which aromatic compounds or heterocyclic aromatic compounds are linked.

Examples of the conjugated polymer include thiophene compounds, pyrrole compounds, aniline compounds, acetylene compounds, p-phenylene compounds, p-phenylene vinylene compounds, p-phenylene ethynylene compounds, p-fluorenylene vinylene compounds, polyacene compounds, polyphenanthrene compounds, metal phthalocyanine compounds, p-xylylene compounds, vinylene sulfide compounds, m-phenylene compounds, naphthalene vinylene compounds, p-phenylene oxide compounds, phenylene sulfide compounds, furan compounds, selenophene compounds, azo compounds, metal complex compounds, and conjugated polymers that have repeating units derived from monomers which are derivatives of these compounds with substituents introduced therein.

Examples of the thiophene compounds and the conjugated polymers that have repeating units derived from the derivatives of the thiophene compounds include polythiophene, a conjugated polymer that includes a repeating unit derived from a monomer obtained by introducing a substituent into a thiophene ring, and a conjugated monomer that includes a repeating unit derived from a monomer having a fused polycyclic structure containing a thiophene ring.

Examples of the conjugated polymer that includes a repeating unit derived from a monomer obtained by introducing a substituent into a thiophene ring include poly-alkyl-substituted thiophenes such as poly-3-methylthiophene, poly-3-butylthiophene, poly-3-hexylthiophene, poly-3-cyclohexylthiophene, poly-3-(2′-ethylhexyl)thiophene, poly-3-octylthiophene, poly-3-dodecylthiophene, poly-3-(2′-methoxyethoxy)methylthiophene, and poly-3-(methoxyethoxyethoxy)methylthiophene; poly-alkoxy-substituted thiophenes such as poly-3-methoxythiophene, poly-3-ethoxythiophene, poly-3-hexyloxythiophene, poly-3-cyclohexyloxythiophene, poly-3-(2′-ethylhexyloxy)thiophene, poly-3-dodecyloxythiophene, poly-3-methoxy(diethyleneoxy)thiophene, poly-3-methoxy(triethyleneoxy)thiophene, and poly-(3,4-ethylenedioxythiophene); poly-3-alkoxy-substituted-4-alkyl-substitued thiophenes such as poly-3-methoxy-4-methylthiophene, poly-3-hexyloxy-4-methylthiophene, and poly-3-dodecyloxy-4-methylthiophene; and poly-3-thioalkylthiophenes such as poly-3-thiohexylthiophene, poly-3-thiooctylthiophene, and poly-3-thiododecylthiophene.

For example, a poly-3-alkylthiophene or a poly-3-alkoxythiophene may be used.

### Organic Charge Transfer Complex

An organic charge transfer complex refers to a complex (D^{γ+}A^{γ-}, where γ represents the amount of charge transfer) generated by charge transfer between an electron donor (D) and an electron acceptor (A).

Not all organic charge transfer complexes have electrical conductivity and thermoelectric properties. Some of organic charge transfer complexes have relatively high electrical conductivity and thermoelectric properties.

Specific examples of the organic charge transfer complexes include p-phenylenediamine-tetracyanoquinodimethane and tetrathiafulvalene-tetracyanoquinodimethane.

### Dopant

The dopant is either an acceptor dopant (p-type dopant) that receives electrons from the organic compound or a donor dopant (n-type dopant) that donates electrons to the organic compound.

Specific examples of the acceptor dopant to be added to the conductive polymer include the following:

(1) halogens such as Cl₂, Br₂, I₂, ICl, ICl₃, IBr, and IF
(2) Lewis acids such as PF₅, AsF₅, SbF₅, BF₃, BCl₃, BBr₃, and SO₃
(3) protonic acids such as HF, HCl, HNO₃, H₂SO₄, HClO₄, and phosphoric acid
(4) organic acids such as 2-naphthalenesulfonic acid, dodecylbenzenesulfonic acid, and camphorsulfonic acid
(5) transition metal compounds such as FeCl3, FeOCl, TiCl₄, ZrCl₄, NbF₅, NbCl₅, TaCl₅, MoF₅, and WF₆

Specific examples of the donor dopant include the following:

(1) alkali metals such as Li, Na, K, Rb, and Cs
(2) alkaline earth metals such as Ca, Sr, and Ba
(3) lanthanoids such as Eu
(4) R₄N⁺, R₄P⁺, R₄As⁺, R₃S⁺ (R: alkyl group), and acetylcholine

A typical fiber has a diameter of 10 to 20 μm and its density is 1.2 to 1.7 g/cm³. The density of the conductive polymer is mostly around 1.5 g/cm³, and in order to cover the fiber with a layer of a conductive polymer having a thickness of 0.1 μm, about 3 wt % of the conductive polymer is to be contained.

When the content of the organic compound selected from the conductive polymers and organic charge transfer complexes having thermoelectric properties reaches about 50 wt % or higher, a coating film having a thickness of about 2 μm is formed, and the number of sites where conductive coating films that bridge between the fibers are formed increases. As a result, flexibility is no longer exhibited, cracking occurs when the transducer is bent or elongated, and the resistance increases as a result.

The conductive polymer is applied so that the content thereof relative to the core for the thermoelectric transducer may be 3 to 50 wt %. In some cases, the content may be, for example, 5 to 25 wt %. The conductive polymer is dried to form a coating film on the surface of the core.

The thickness of the coating film formed of the conductive polymer is 0.1 to 2.5 μm and may be 0.2 to 2.2 μm.

When the thickness of the coating film formed of the conductive polymer is within this range, there may be less cracking caused by bending.

Examples of the method for forming a coating film on a stretchable core by using the conductive polymer include a method that involves immersing the core in a conductive polymer solution to allow the conductive polymer to permeate the core naturally or under pressure; a method that involves placing the core in a container, creating vacuum or reducing the pressure in the container, and then adding a coating solution to allow the coating solution to permeate the core; a method that involves allowing a coating solution to permeate the core by mechanical pressure; and a method that involves compressing the core so as to eliminate air as much as possible, and then immersing the core in a coating solution so as to cause the coating solution to permeate the core.

The coating film formed of a conductive polymer and formed on a stretchable core can cover not only the surface of the twisted thread formed of a non-stretchable or stretchable material constituting the core, but also the surfaces of individual fibers constituting the twisted thread.

Before permeation, the core can be surface-treated by being washed with an acid, an alkali, an organic solvent, a surfactant, or the like.

Drying can be performed at a reduced pressure and under heating, in vacuum, in an inert atmosphere such as a nitrogen atmosphere, or the like.

### EXAMPLES

Examples and Comparative Examples of the present disclosure will now be described. These examples are not limiting.

### Preparation of Coating Solution

Ten grams of a poly(3,4-ethylenedioxythiophene):poly(4-styrenesulfoic acid salt) (PEDOT:PSS) solution (WED-SM produced by Soken Chemical & Engineering Co., Ltd.) having a solid content of 1.5 wt % was thoroughly stirred to prepare a coating solution. The conductive polymer concentration of the coating solution was 1.5 wt %.

### Example 1

A cotton elastic bandage (produced by Hakujuji Co., Ltd., width: 50 mm) with spandex woven thereinto was used as the core. This elastic bandage was cut to a width of 50 mm and a length of 130 mm to prepare a core. The weight of the core was 0.72 g.

Onto the core, 1.5 g of the coating solution described above was dropped, pressure was applied so that the coating solution fully penetrated the core, and then heating was performed at 70° C. for 10 minutes to dry the core. As a result, a bendable and stretchable thermoelectric transducer that included a coating film and had a conductive polymer content of 3 wt % was prepared.

### Example 2

Onto the core the same as that in Example 1, 1.5 g of the coating solution was dropped, the core was rubbed so that the coating solution fully penetrated the core, and then heating was conducted at 70° C. for 10 minutes to dry the core. This process was performed 8 times. As a result, a bendable and stretchable thermoelectric transducer that included a coating film and had a conductive polymer content of 24 wt % was prepared.

### Example 3

A stretchable cloth made of cotton with rubber woven thereinto was used as the core. The core had a width of 50 mm, a length of 130 mm, and a weight of 0.7 g.

Onto the core, 1.5 g of the coating solution was dropped, the core was rubbed so that the coating solution fully penetrated the core, and then heating was conducted at 70° C. for 10 minutes to dry the core. This process was performed 5 times. As a result, a bendable and stretchable thermoelectric transducer that included a coating film and had a conductive polymer content of 14 wt % was prepared.

### Example 4

A stretchable cloth made of aramid fibers with spandex woven thereinto was used as the core. The core had a width of 50 mm, a length of 130 mm, and a weight of 0.75 g.

Onto the core, 1.5 g of the coating solution was dropped, the core was rubbed so that the coating solution fully penetrated the core, and then heating was conducted at 70° C. for 10 minutes to dry the core. This process was performed 5 times. As a result, a bendable and stretchable thermoelectric transducer that included a coating film and had a conductive polymer content of 13 wt % was prepared.

### Example 5

A cotton elastic bandage (produced by Hakujuji Co., Ltd.) with spandex woven thereinto was used as the core. The core had a width of 50 mm. The core was cut to a width of 50 mm and a length of 130 mm. The weight of the cut-out core was 0.72 g. A 1 wt % coating solution was prepared by dissolving poly[2-methoxy-5-(2-ethylhexyloxy)-1,4-phenylenevinylene] (hereinafter referred to as MEH-PPV) produced by SIGMA-ALDRICH Co. LLC., in chloroform. Onto the core, 1.5 g of the coating solution was dropped, the core was rubbed so that the coating solution fully penetrated the core, and drying was conducted at room temperature (23° C.) for 2 hours at a reduced pressure (2 mmHg (about 266 N·m⁻²)). This process was performed 10 times. Then vapor phase doping (vapor pressure: 1 mmHg (about 133 N·m⁻²)) was conducted by using iodine as a dopant. As a result, a bendable and stretchable thermoelectric transducer that included a coating film and had a conductive polymer content of 17 wt % was prepared.

### Example 6

Onto the core the same as that in Example 1, 1.5 g of the coating solution was dropped, the core was rubbed so that the coating solution fully penetrated the core, and then heating was conducted at 70° C. for 10 minutes to dry the core. This process was performed 15 times. As a result, a bendable and stretchable thermoelectric transducer that included a coating film and had a conductive polymer content of 44 wt % was prepared.

### Example 7

Onto the core the same as that in Example 1, 1.3 g of the coating solution was dropped, the core was rubbed so that the coating solution fully penetrated the core, and then heating was conducted at 70° C. for 10 minutes to dry the core. This process was performed twice. As a result, a bendable and stretchable thermoelectric transducer that included a coating film and had a conductive polymer content of 5 wt % was prepared.

### Example 8

Onto the core the same as that in Example 1, 1.5 g of the coating solution was dropped, the core was rubbed so that the coating solution fully penetrated the core, and then heating was conducted at 70° C. for 10 minutes to dry the core. This process was performed 7 times. As a result, a bendable and stretchable thermoelectric transducer that included a coating film and had a conductive polymer content of 20 wt % was prepared.

### Example 9

Onto the core the same as that in Example 1, 1.5 g of the coating solution was dropped, the core was rubbed so that the coating solution fully penetrated the core, and then heating was conducted at 70° C. for 10 minutes to dry the core. This process was performed 17 times. As a result, a bendable and stretchable thermoelectric transducer that included a coating film and had a conductive polymer content of 50 wt % was prepared.

### Comparative Example 1

A cotton elastic bandage (produced by Hakujuji Co., Ltd.) with spandex woven thereinto was used as the core. The core had a width of 50 mm. The core was cut to a width of 50 mm and a length of 130 mm. The weight of the cut-out core was 0.77 g. Onto the core, 0.3 g of the coating solution was dropped, the core was rubbed so that the coating solution fully penetrated the core, and heating was conducted at 70° C. for 10 minutes to dry the core. As a result, a bendable and stretchable thermoelectric transducer that included a coating film and had a conductive polymer content of 0.5 wt % was prepared.

### Comparative Example 2

A cotton elastic bandage (produced by Hakujuji Co., Ltd.) with spandex woven thereinto was used as the core. The core had a width of 50 mm. The core was cut to a width of 50 mm and a length of 130 mm. The weight of the cut-out core was 0.72 g. Onto the core, 1.5 g of the coating solution was dropped, the core was rubbed so that the coating solution fully penetrated the core, and heating was conducted at 70° C. for 10 minutes to dry the core. This process was performed 20 times. As a result, a thermoelectric transducer that included a coating film and had a conductive polymer content of 60 wt % was prepared.

### Comparative Example 3

A cotton elastic bandage (produced by Hakujuji Co., Ltd.) with spandex woven thereinto was used as the core. The core had a width of 50 mm. The core was cut to a width of 50 mm and a length of 130 mm. The weight of the cut-out core was 0.75 g. Bi₂Te₃ was used as the thermoelectric material. Onto the core, 0.25 g of Bi₂Te₃ powder having an average particle diameter of 2.3 μm was evenly attached and sintered by using a discharge plasma sintering system at a temperature elevation rate of 100° C./min, a sintering temperature of 300° C., a sintering pressure of 49 MPa for a sintering time of 3 minutes to obtain a thermoelectric transducer. However, under these conditions, a satisfactory coating film was not formed.

### Comparative Example 4

A 150 mm×150 mm center portion of a 200 mm×200 mm silicone rubber plate having a thickness of 10 mm was bored to form a silicone rubber plate mask. This mask was placed on a base, i.e., a 200 mm×200 mm silicone rubber plate having a thickness of 0.5 mm, and 10 g of the coating solution was poured into the bored 150 mm×150 mm center portion of the mask, followed by heating and drying at 70° C. for 60 minutes. Then the silicone rubber plate mask having a thickness of 3 mm was removed. As a result, a thermoelectric material having a thickness of 5.2 μm was obtained.

The thermoelectric material was cut together with the silicone rubber plate that constituted the base and subjected to evaluation on the base. However, evaluation of the difference in elongation between before and after incorporation of the thermoelectric material was not performed because this was a comparative example formed of a thermoelectric material 100% and the state before incorporation of the thermoelectric material was inconceivable.

### Measurement and Evaluation Methods

### Method for Preparing Test Piece

A rectangular test piece 5 cm in length and 13 cm in width was prepared. As illustrated in FIG. 3, the two ends in the elongating direction are electrically connected to copper electrodes. For example, each end of the test piece was placed on a copper tape, and a conductive silver paste (DOTITE produced by Fujikura Kasei Co., Ltd.) was used to electrically connect and fix the test piece to the copper tape.

### Method for Determining Electromotive Force

As illustrated in FIG. 3, the electrodes at the two ends were respectively maintained at 60±5° C. at the high temperature side and 20±5° C. at the low temperature side. A digital electrometer TR8652 (produced by ADVANTEST CORPORATION) was connected to the electrodes and the earth so as to measure the voltage between the electrodes and determine the electromotive force caused by the Seebeck effect.

### Method for Measuring Resistance

The resistance was measured by a four-terminal method by replacing the digital electrometer TR8652 (produced by ADVANTEST CORPORATION) illustrated in FIG. 3 with Loresta GPMCP-T600 (produced by Mitsubishi Chemical Analytech Co., Ltd.).

### Bending Resistance Test

The test piece described above was subjected to 150 times of double bending at a bending angle of from 180° to −180° at the same middle position of the test piece between the electrodes. The resistance of the test piece before bending and the resistance of the test piece after bending was measured and the rate of increase in resistance was determined.

The percentage rate of increase in resistance was calculated from the following equation:

Rate of increase in resistance (%)=resistance value after testing/resistance value before testing×100

### Evaluation of Bending Resistance

A: The rate of increase in resistance was less than 110%.
B: The rate of increase in resistance was 110% to 120%.
C: The rate of increase in resistance was greater than 120%.
D: The resistance value before bending was 10,000 or more.

### Stretch Resistance Test

The resistance of the test piece was measured while the test piece was stretched in the stretchable direction so that the length thereof was 1.5 times that of a normal state, and the rate of increase in resistance was calculated. The percentage rate of increase in resistance was calculated from the following equation:

Rate of increase in resistance (%)=resistance value after testing/resistance value before testing×100

### Evaluation of Stretch Resistance

A: The rate of increase in resistance was less than 110%.
B: The rate of increase in resistance was 110% to 120%.
C: The rate of increase in resistance was greater than 120%.
D: The resistance value before elongation was 10,000 or more.
Method for Determining Difference in Elongation Between Before and after Incorporation of Thermoelectric Material

The elongation of the substrate at the elastic limit was measured before incorporation of the thermoelectric material. The measurement method involved pinching the substrate at 1 cm end portions in the stretching direction of the substrate by using clips and the like to fix the substrate, suspending the substrate from a sufficient height, hanging a weight from the fixed lower end portion of the substrate to determine elongation, measuring the load at which the elastic limit was reached, and determining the elongation at the elastic limit. The elongation at the elastic limit after incorporation of the thermoelectric material was measured in the same manner. The difference in elongation between before and after incorporation of the thermoelectric material was calculated from the following equation:

Difference in elongation=elongation at elastic limit before incorporation of thermoelectric material−elongation at elastic limit after incorporation of thermoelectric material

Evaluation of Difference in Elongation Between Before and after Incorporation of Thermoelectric Material
A: The difference in elongation was less than 10%.
B: The difference in elongation was 10% to 20%.
C: The difference in elongation was greater than 20%.
D: No elastic change was shown.
Method for Measuring Elongation Under Stress Load at Elastic Limit Before and after Incorporation of Thermoelectric Material, and Definitions

The length of the core under zero stress was measured, and the length of the core under tensile stress at elastic limit was measured to determine the elongations before and after incorporation of the thermoelectric material.

In the same manner, the length of the thermoelectric transducer under zero stress was measured, and the length of the thermoelectric transducer under tensile stress at elastic limit was measured to determine the elongations before and after incorporation of the thermoelectric material from the following equation:

Elongation (%)=length under tensile stress at elastic limit/length under zero stress×100

### Measurement of Coating Thickness

The average size (diameter of a fiber) of the core (fiber) before being covered and the average size after being covered were measured with a scanning electron microscope (SEM). The difference in average size between before and after covering was assumed to be the thickness of the coating film.

### Comprehensive Evaluation

Those samples in which no electromotive force was confirmed were rated D.

### Comprehensive Evaluation Based on Evaluation Results on Bending Resistance, Stretch Resistance, and Elongation

A: Samples rated A in all three items.
B: Samples rated B in one or more items but A in other items.
C: Samples rated C in one or more items but A or B in other items.
D: Samples rated D in one or more items.

The evaluation results of the thermoelectric transducers prepared in Examples 1 to 9 and Comparative Examples 1 to 4 for the bending resistance, stretch resistance, and elongation are summarized in the table below.

TABLE

| | Non-stretchable | | | | | Coating | Bending resistance | | | |
|---|---|---|---|---|---|---|---|---|---|---|
| | fiber | | Stretchable | Thermoelectric | Thermoelectric | film | Before | After | Rate of | |
| | | Diameter | fiber | material | material | thickness | bending | bending | increase in | Evaluation |
| | Type | [μm] | Type | Type | content (%) | (μm) | [kΩ] | [kΩ] | resistance | results |
| Example 1 | Cotton | 12 | Spandex | PEDOT:PSS | 3 | 0.2 | 32 | 37 | 116% | B |
| Example 2 | Cotton | 12 | Spandex | PEDOT:PSS | 24 | 1.5 | 5.0 | 5.4 | 108% | A |
| Example 3 | Cotton | 12 | Natural | PEDOT:PSS | 14 | 0.8 | 15 | 16 | 107% | A |
| | | | rubber | | | | | | | |
| Example 4 | Aramid | 15 | Spandex | PEDOT:PSS | 13 | 0.8 | 18 | 19 | 106% | A |
| Example 5 | Cotton | 12 | Spandex | MEH-PPV | 17 | 1.0 | 12 | 13 | 108% | A |
| Example 6 | Cotton | 12 | Spandex | PEDOT:PSS | 44 | 2 | 3.5 | 5.1 | 146% | C |
| Example 7 | Cotton | 12 | Spandex | PEDOT:PSS | 5 | 0.3 | 26 | 28 | 108% | A |
| Example 8 | Cotton | 12 | Spandex | PEDOT:PSS | 20 | 1.3 | 5.8 | 6.2 | 107% | A |
| Example 9 | Cotton | 12 | Spandex | PEDOT:PSS | 50 | 2.2 | 2.8 | 5.3 | 189% | C |
| Comparative | Cotton | 12 | Spandex | PEDOT:PSS | 0.5 | 0.02 | 10000 or | 10000 or | — | D |
| Example 1 | | | | | | | higher | higher | | |
| Comparative | Cotton | 12 | Spandex | PEDOT:PSS | 60 | 7.3 | 2.2 | Undetectable | — | D |
| Example 2 | | | | | | | | due to | | |
| | | | | | | | | cracks in | | |
| | | | | | | | | coating film | | |
| Comparative | Cotton | 12 | Spandex | Bi₂Te₃ | 25 | Satisfactory | 10000 or | 10000 or | — | D |
| Example 3 | | | | | | coating film | higher | higher | | |
| | | | | | | was not | | | | |
| | | | | | | formed | | | | |
| Comparative | None | None | None | PEDOT:PSS | 100 | 5.2 | 10000 or | 10000 or | — | D |
| Example 4 | | | | | | | higher | higher | | |

| | | | | | Elongation | | | |
|---|---|---|---|---|---|---|---|---|
| | | | | | Difference in | | | |
| | Stretch resistance | | | | elongation between | | Electromotive | |
| | When | When | Rate of | | before and after | | force | Comprehensive |
| | contracted | elongated | increase in | Evaluation | incorporation of | Evaluation | μV/K | evaluation |
| | [kΩ] | [kΩ] | resistance | results | thermoelectric material | results | 10.5 | B |
| Example 1 | 32 | 33 | 103% | A | 2% | A | 10.3 | A |
| Example 2 | 5.0 | 5.1 | 102% | A | 8% | A | 10.3 | A |
| Example 3 | 15 | 16 | 107% | A | 5% | A | 10.4 | A |
| Example 4 | 18 | 18 | 100% | A | 5% | A | 40.3 | B |
| Example 5 | 12 | 14 | 117% | B | 6% | A | 10.1 | C |
| Example 6 | 3.5 | 6.5 | 186% | C | 13% | B | 10.5 | A |
| Example 7 | 26 | 27 | 104% | A | 3% | A | 11.1 | A |
| Example 8 | 5.8 | 6.3 | 109% | A | 9% | A | 10.3 | C |
| Example 9 | 2.8 | 5.5 | 196% | C | 15% | B | Undetectable | D |
| Comparative | 10000 or | 10000 or | — | D | 0 | A | 10.1 | D |
| Example 1 | higher | higher | | | | | | |
| Comparative | 2.2 | Undetectable | — | D | Undetectable | D | Undetectable | D |
| Example 2 | | due to cracks in | | | due to no | | | |
| | | coating film | | | elongation | | | |
| Comparative | 10000 or | Undetectable | — | D | Undetectable | D | 10.5 | D |
| Example 3 | higher | due to cracks in | | | due to no | | | |
| | | coating film | | | elongation | | | |
| Comparative | 10000 or | 10000 or | — | D | Undetectable | — | 10.5 | B |
| Example 4 | higher | higher | | | due to no | | | |
| | | | | | elongation | | | |

It was found that the thermoelectric transducers obtained in Examples 1 to 9 had a coating film having a thickness of 0.1 to 2.5 μm.

In bending resistance evaluation that involved 150 times of 180° to −180° double bending, the thermoelectric transducers obtained in Examples 1 to 9 exhibited a rate of increase in resistance of 105% to 195% in terms of change in resistance between before and after bending, and thus were found to maintain electrical conductivity.

The resistance values of the thermoelectric transducers obtained in Examples 1 to 9 and the resistance values of the transducers elongated to 1.5 times the original length were compared. The rate of increase in resistance was 100% to 200%, and it was found that the transducers maintained electrical conductivity.

The change in elongation between the core before treatment with a conductive polymer or an organic charge transfer complex and the thermoelectric transducer obtained after the treatment was evaluated. It was found that the difference in elongation was within the range of 1% to 20%.

Lastly, the electromotive force of the thermoelectric transducers obtained in Examples 1 to 9 was evaluated and was found to be 9 to 42 μV/K.

When the evaluation results of the thermoelectric transducers obtained in Examples 1 to 9 and Comparative Examples 1 and 2 are studied from the viewpoint of the bending resistance, it was found that the thermoelectric material content relative to the core for the thermoelectric transducers may be 3 to 50 wt % or, as long as the stretch resistance is sufficient, may be 5 to 25 wt %.

It was found that when the thermoelectric material content is smaller than 3 wt %, a satisfactory coating film is rarely formed and that uncovered portions may remain.

It was found that when the thermoelectrical material content is greater than 50 wt %, the flexibility of the coating film is poor, and the coating film would crack due to the thermoelectric material, resulting in degraded performance.

It was found that, from the viewpoint of the bending resistance, the thickness of the coating film may be 0.1 to 2.5 μm or, as long as stretch resistance is sufficient, may be 0.2 to 2.2 μm.

It was found that when the coating film has a thickness smaller than 0.1 μm, a satisfactory film may not be formed and performance of the thermoelectric transducer may be degraded due to the presence of uncovered portions.

It was found that when the coating film has a thickness larger than 2.5 μm, a coating film cracks, and the performance of the thermoelectric transducer is degraded.

It was found that when the difference in elongation between before and after incorporation of the thermoelectric material is 20% or less, the cores performs as satisfactorily as the core before formation of the coating film with the thermoelectric material, and that when the difference is 10% or less, the core highly endures repeating cycles.

With the thermoelectric transducer obtained in Comparative Example 1 in which the conductive polymer content was excessively low, the conductive polymer thin films that lie between fibers within one sheet of the thermoelectric transducer could not sufficiently be electrically connected, conduction could not confirmed when bent or stretched, and no electromotive force was confirmed.

With the thermoelectric transducer obtained in Comparative Example 2 in which the conductive polymer content was excessively high, the thickness of the conductive polymer films between the fibers increased and the flexibility was impaired. As a result, cracking occurred when bent or stretched, and issues such as an increase in resistance and lack of elastic change arose.

With the thermoelectric transducer obtained in Comparative Example 3, the non-stretchable fibers and the stretchable fibers were decomposed as a result of sintering, and the films of the thermoelectric material could not be formed on the core.

It is a typical practice to perform forming by sintering for inorganic thermoelectric transducers; thus it was found that further improvements are desirable if inorganic thermoelectric materials are to be used.

The thermoelectric transducer obtained in Comparative Example 4 exhibited some degree of flexibility but cracked when bent. Moreover, the thermoelectric transducer could not be elongated to 1.5 times the original length and cracked.

According to the present disclosure, each of the fibers that constitute a stretchable core is thinly covered with a conductive polymer having thermoelectric properties. Thus, flexibility that allows the thermoelectric transducer to be bendable is realized, and the electrical conductivity is improved since the fibers covered with the conductive polymer are connected side by side when viewed as a whole. According to the present disclosure, flexibility that achieves bendability and electrical conductivity can be both achieved.

The present disclosure contains subject matter related to that disclosed in Japanese Priority Patent Application JP 2016-154598 filed in the Japan Patent Office on Aug. 5, 2016, the entire contents of which are hereby incorporated by reference.

It should be understood by those skilled in the art that various modifications, combinations, sub-combinations and alterations may occur depending on design requirements and other factors insofar as they are within the scope of the appended claims or the equivalents thereof.

What is claimed is:

1. A thermoelectric transducer comprising:
a core that is stretchable and bendable; and
a coating film on a surface of the core, the coating film being formed of an organic compound selected from conductive polymers and organic charge transfer complexes that have thermoelectric properties.

2. The thermoelectric transducer according to claim 1, wherein the core is formed of a non-stretchable material with a stretchable material woven thereinto.

3. The thermoelectric transducer according to claim 1, wherein the conductive polymer is a polythiophene compound or a polyphenylene vinylene compound, and the organic charge transfer complex is p-phenylenediamine-tetracyanoquinodimethane or tetrathiafulvalene-tetracyanoquinodimethane.

4. The thermoelectric transducer according to claim 1, wherein a content of the coating film relative to the core is 3 to 50 wt %.

5. The thermoelectric transducer according to claim 1, wherein the core is formed of a fiber or a twisted thread of fibers, and a surface of the fiber or the twisted thread is covered.

6. The thermoelectric transducer according to claim 1, wherein the coating film has a thickness of 0.1 to 2.5 μm.

7. The thermoelectric transducer according to claim 1, wherein the coating film has a thickness of 0.2 to 2.2 μm.

8. The thermoelectric transducer according to claim 1, wherein the core is formed of a fiber.

9. The thermoelectric transducer according to claim 1, wherein a difference in elongation between the thermoelectric transducer and the core alone without the coating film is 20% or less under tensile stress load at elastic limit.
